(19) United States
(12) Patent Application Publication
(10) Pub. No.: US 2009/0114960 A1
(43) Pub. Date: May 7, 2009

(54) Image Sensor and a Method for Manufacturing the Same

(76) Inventors: Ju Hyun Kim, Cheonan-si (KR); Jae Hyun Kang, Suwon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/209,348

(22) Filed: Sep. 12, 2008

(30) Foreign Application Priority Data
Nov. 5, 2007 (KR) 10-2007-0112162

(51) Int. Cl. H01L 31/00; H01L 21/00

(52) U.S. Cl. 257/292; 438/70; 257/E31.001; 257/E21.001

(57) ABSTRACT

An image sensor and method for manufacturing the same are provided. According to an embodiment, the image sensor includes a photodiode on a semiconductor substrate according to unit pixels; an insulating layer arranged on the semiconductor substrate; and an inter metal dielectric (IMD) including metal wirings arranged on the insulating layer. A trench is provided through the IMD in a region corresponding to the photodiode for each unit pixel; and a color filter is arranged filling the trench. The color filter can function as a wave guide to improve the photosensitivity of the image sensor.

### CROSS-REFERENCE TO RELATED APPLICATION

The present application claims the benefit under 35 U.S.C. §119 of Korean Patent Application No. 10-2007-0112162, filed Nov. 5, 2007, which is hereby incorporated by reference in its entirety.

### BACKGROUND

An image sensor is a semiconductor device that converts an optical image into an electrical signal. Image sensors are typically classified as charge coupled device (CCD) image sensors or complementary metal oxide semiconductor (CMOS) image sensors (CIS).

The CIS utilizes a photodiode and a MOS transistor in a unit pixel and sequentially detects the electrical signal generated by the photodiode in each unit pixel in a switching manner to implement an image.

As design rules for structures in the CIS gradually decrease, the size of the unit pixel has decreased, resulting in decreased photosensitivity. A microlens is often formed on a color filter layer to increase the photosensitivity.

However, the photosensitivity may be decreased by diffraction and scattering of light due to a redistribution layer that exists in an optical path from the microlens to a photodiode.

### BRIEF SUMMARY

Embodiments of an image sensor and method for manufacturing the same are provided.

An image sensor according to an embodiment can comprise a photodiode on a semiconductor substrate; an insulating layer on the semiconductor substrate; an inter metal dielectric (IMD) including a metal wiring on the insulating layer; a trench formed in the IMD at a region corresponding to the photodiode; and a color filter arranged in the trench.

In an embodiment, a method for manufacturing an image sensor can include forming a photodiode on a semiconductor substrate; forming an insulating layer on the semiconductor substrate; forming an IMD including a metal wiring on the insulating layer; forming a trench in the IMD at a region corresponding to the photodiode; and forming a color filter so as to fill the inside of the trench.

### BRIEF DESCRIPTION OF THE DRAWINGS

FIGS. 1 to 6 are cross-sectional views showing a manufacturing process of an image sensor according to an embodiment of the present invention.

### DETAILED DESCRIPTION

Embodiments of an image sensor and a method for manufacturing the same will be described with reference to the accompanying drawings.

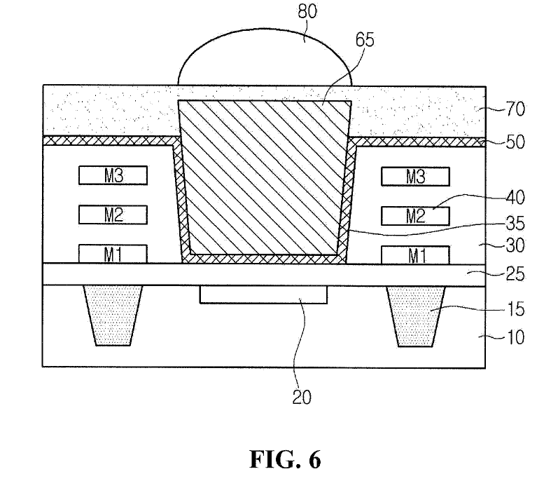

FIG. 6 is a cross-sectional view showing an image sensor according to an embodiment.

Referring to FIG. 6, an insulating layer 25 can be arranged on a semiconductor substrate 10 including a photodiode 20 and at least one MOS transistor (not shown).

The photodiode 20 that receives light to generate photo charges and the transistor (not shown) that is connected to the photodiode 20 to convert the photo charges into electrical signals can be arranged on the semiconductor substrate 10 according to unit pixel.

The insulating layer 25 can be a pre-metal dielectric (PMD), which is an insulating layer before a metal wiring. In one embodiment, the insulating layer 25 can be formed of an un-doped silicate glass (USG).

Above the insulating layer 25 is arranged an inter metal dielectric (IMD) 30 including metal wirings (M1, M2, M3) 40. The IMD 30 can be formed in plural layers. Also, the IMD 30 can be formed of insulating material different from the insulating layer 25. For example, the IMD 30 can include an oxide film and/or a nitride film.

The metal wiring 40 is arranged penetrating through the IMD 30. The metal wiring 40 can be arranged according to layers of the IMD 30 and can be electrically connected to each other to provide power and signal lines to structures on the substrate. Also, the metal wiring 40 can be arranged so as to not interfere with incident light to the photodiode 20. That is, the metal wirings can be arranged in regions not corresponding to the photodiode 20.

A trench 35 can be provided in the IMD 30 at a region corresponding to the photodiode 20. The trench 35 can be formed to expose a surface of the insulating layer 25 above the photodiode 20. The trench 35 can be formed per unit pixel in the IMD 30 to correspond to each photodiode 20. According to embodiments, the trench 35 can extend through the IMD 30 passed below the metal wirings 40.

In one embodiment, a barrier layer 50 can be formed on the (IMD) 30 including the trench 35. The barrier layer 50, which is to protect a device including the photodiode 20, can be formed of, for example, a silicon nitride film. The barrier layer 50 is formed at a thin thickness so that it can be arranged along a step between the IMD 30 and the trench 35.

A color filter 65 can be provided in the trench 35. The color filter 65 can fill the trench 35 so that it can have the same height as the barrier layer 50 or the IMD 30 on the metal wiring 40. In another embodiment, the color filter 65 can be formed to have the height higher than the barrier layer 50 on the metal wiring 40.

The color filter 65 can be formed of material for filtering different wavelengths of colors. For example, the color filters 65 can be any one of red, blue, and green color filters. In one embodiment, the color filter can be formed of dyable or pigmented resist.

The color filter 65 is arranged in the trench 35 such that the spaced distance of the color filter 65 and the photodiode 20 can be in proportion to the thickness of the insulating layer 25. Accordingly, the photodiode 20 and the color filter 65 can be arranged to approach to each other.

A planarization layer 70 can be provided on the IMD 30 including the color filter 65. The color filter 65 may have a step difference between neighboring color filters 65. A microlens 80 which is formed on the color filter 65 should be formed on the planarized surface.

Accordingly, a planarization layer 70 can be provided on the color filter 65 to remove any step difference generated due to the formation of different color filters 65. Of course, the planarization layer 70 may be omitted.

A microlens 80 can be arranged on the planarization layer 70 corresponding to the color filter 65. The microlens 80 can be formed in a dome type, making it possible to collect and condense light into the photodiode 20.

With the image sensor according to embodiments, the color filter is formed in the trench of the inter-metal dielectric layers, making it possible to improve the photosensitivity of the photodiode.

Also, the color filter in the trench can perform a role of a wave guide of the incident light so that the diffraction and the scattering of light can be inhibited, making it possible to improve the condensing ratio of the photodiode.

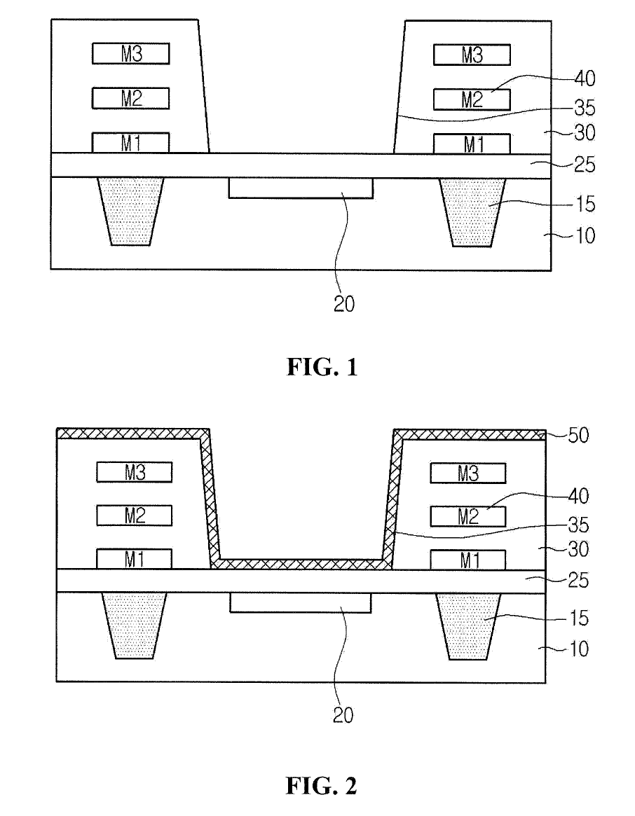

A manufacturing process of an image sensor according to an embodiment will be described in detail with reference to FIGS. 1-6.

Referring to FIG. 1, a device isolating layer 15, which defines an active region and a field region, can be formed on a semiconductor substrate 10. In addition, a photodiode 20 that receives light to generate photo charges and a transistor (not shown) that is connected to the photodiode 20 to convert the received photo charges into electrical signals can be formed in the active region for each unit pixel.

An insulating layer 25 can be formed on the semiconductor substrate 10 above the photodiode 20. The insulating layer 25 can be a pre-metal dielectric (PMD), which is an insulating layer before a metal wiring. In one embodiment, the insulating layer 25 can be formed of an un-doped silicate glass (USG).

Although not shown, a contact plug can be formed in the insulating layer 25 to contact diffusion regions and gate electrodes on the substrate and may be electrically connected to the subsequently formed metal wiring.

An IMD 30 including the metal wirings (M1, M2, M3) 40 can be formed on the insulating layer 25.

The IMD 30 can be formed in a plurality of layers. For example, the IMD 30 can be formed of any one of a nitride film, an oxide film, and an oxynitride film, or in a structure where one or more layers are stacked. Particularly, the IMD 30 may be formed of an insulating material different from the insulating layer 25.

A plurality of metal wirings 40 may be formed penetrating through the IMD 30. The metal wirings 40 and IMD 30 can be formed according to any suitable method known in the art. For example, a damascene or dual damascene process can be used. Alternatively, or in addition, a deposition and patterning process can be used. The M1, M2 and M3, referred to as metal wiring 40, may be connected to each other. Also, the metal wiring 40 is intentionally formed in a layout so as not to cover the photodiode 20. Although three layers of metal wirings 40 are illustrated in the drawings, embodiments are not limited thereto.

Next, a trench 35 can be formed in the IMD 30. The trench 35 can be formed by etching the IMD 30 in a region corresponding to the photodiode 20. According to an embodiment, the trench 35 can be formed by forming a photoresist pattern (not shown) on the IMD 30 exposing the IMD 30 in a region corresponding to the photodiode 20, and then etching the exposed IMD 30 using the photoresist pattern as an etching mask. In an embodiment, the insulating layer 25 can be used as an etching end-point upon forming the trench 35. Accordingly the trench 35 can be formed spaced from the photodiode 20 by a thickness of the insulating layer 25.

The trench 35 can be formed for each unit pixel to correspond to the photodiode 20 of each unit pixel.

In one embodiment, referring to FIG. 2, a barrier layer 50 can be formed on the IMD 30 including the trench 35. The barrier layer 50, which is to protect a device including the photodiode 20, can be formed of an insulating layer. For example, the barrier layer 50 can be formed of any one of a silicon oxide film, a silicon nitride film, and a silicon oxynitride film, or may be formed in a structure where one or more layer is stacked.

The barrier layer 50 is deposited at a thin thickness and can be formed along a step between the IMD 30 and the trench 35. Therefore, the barrier layer 50 can be formed on a surface of the insulating layer 25 and a side surface of the IMD 30 through the trench 35. At this time, the barrier layer 50 is formed at a thin thickness, so that the inside of the trench 35 can be maintained in the appropriate shape.

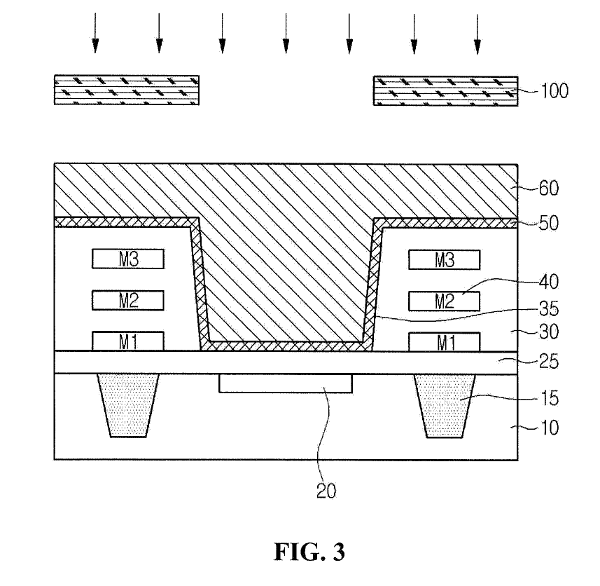

Referring to FIG. 3, a color filter layer 60 can be formed on the (IMD) 30 including the trench 35. The color filter layer 60 can be formed completely filling the trench 35. The color filter layer 60 can be formed to reach a top surface of the barrier layer 50 on the metal wiring 40. In certain embodiments, the color filter layer 60 can extend above the trench 35 higher than the barrier layer 50 and the IMD 30.

The color filter layer 60 can be formed of material for filtering various colors. For example, the color filter layer 60 can be a red color filter layer, a green color filter layer, or blue color filter layer.

The color filter layer 60 can be formed by performing a spin coating process to coat materials for the color filter on the substrate. For example, photosensitive material and pigment or photosensitive material and dye can be coated on the (IMD) 30 including the trench 35. In certain embodiments, the color filter layer 60 can be a positive type or a negative type resist. In the embodiment described below, the color filter layer 60 is formed of negative type resist.

Accordingly, the material for the color filter can be exposed and developed by the pattern mask 100, making it possible to form the color filter 65 in the trench 35. As shown in FIG. 3, the pattern mask 100 exposing a region of the color filter layer 60 corresponding to the trench 35 is positioned above the color filter layer 60. Then, the color filter layer 60 is exposed using the pattern mask 100 and developed.

Because the color filter layer 60 uses the negative type resist, regions of the color filter layer 60 other than on the trench 35 are removed by the exposure and development processes.

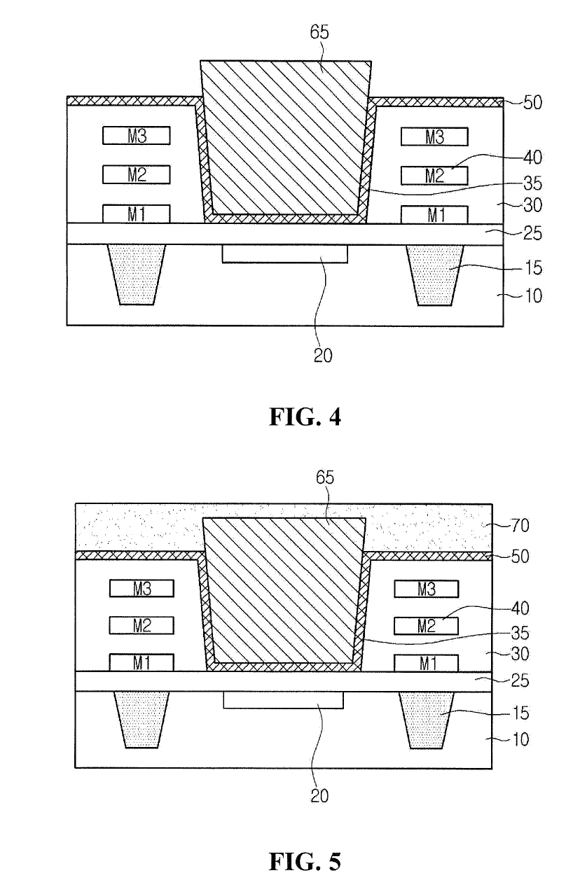

Accordingly, as shown in FIG. 4, the color filter 65 remains only on the region of the trench 35. The color filter 65 can be formed per unit pixel by means of the trench 35, making it possible to separate colors from incident light.

By forming the color filter 65 in the trench 35, the color filter 65 has the spaced distance from the photodiode based on the thickness of the insulating layer 25. Therefore, the color filter 65 is formed to approach the photodiode 20 so that an optical path of the incident light is decreased, making it possible to improve the photosensitivity of the image sensor.

Also, the color filter 65 is formed to completely fill in the trench 35 so that it can perform the role of a wave guide of an incident light. Therefore, the diffusion and diffraction of the light can be reduced, making it possible to improve a condensing ratio to the photodiode 20.

Also, by not filling inside of the trench 35 with a separate material for creating a wave guide and using the color filter 65 as the waveguide inside of the trench, process steps can be decreased, thereby improving yield.

Referring to FIG. 5, a planarization layer 70 can be formed on the IMD 30 including the color filter 65. A microlens should be formed on a planar surface. Therefore, since a step due to the color filter 65 should be removed, the planarization layer 70 may be formed on the color filter 65. Of course, the planarization layer 70 can be omitted.

Referring FIG. 6, a microlens 80 can be formed on the planarization layer 70 in a region corresponding to the color filter 65. The microlens 80 can be formed according to unit pixel, making it possible to collect light into each photodiode 20.

The microlens 80 can be formed of a silicon oxide film having high light transmittance or a photosensitive photoresist. In one embodiment using photosensitive resist, the resist can be patterned into a lens pattern to correspond to each photodiode 20 arranged per unit pixel. Then, a reflow process can be performed on the lens pattern so that the microlens 80 of a dome type can be formed per unit pixel.

With a method for manufacturing an image sensor according to embodiments of the present invention, the color filter is formed in a trench through the IMD layer, making it possible to improve the photosensitivity of the image sensor.

Also, the color filter can be formed to completely fill in the trench, making it possible to perform a role of a wave guide of an incident light.

Because the color filter can be formed in the trench, the materials performing a role of a separate wave guide are not needed, thereby reducing the process steps and cost, and consequently, improving productivity.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate including a photodiode;
an insulating layer on the semiconductor substrate;
an inter metal dielectric (IMD) including metal wirings on the insulating layer, the IMD comprising a trench extending through the IMD in a region corresponding to the photodiode; and
a color filter in the trench.

2. The image sensor according to claim 1, wherein a top surface of the color filter has the same height as a top surface of the IMD.

3. The image sensor according to claim 1, wherein a top surface of the color filter has a height higher than a top surface of the IMD.

4. The image sensor according to claim 1, further comprising a planarization layer on the color filter.

5. The image sensor according to claim 1, further comprising a barrier layer arranged between surfaces of the trench and the color filter.

6. The image sensor according to claim 5, wherein the barrier layer comprises insulative material.

7. The image sensor according to claim 1, wherein the trench exposes the insulating layer in the region corresponding to the photodiode.

8. The image sensor according to claim 1, further comprising a microlens on the color filter.

9. A method for manufacturing an image sensor comprising:
forming a photodiode on a semiconductor substrate;
forming an insulating layer on the semiconductor substrate;
forming an inter metal dielectric (IMD) including metal wirings on the insulating layer;
forming a trench through the IMD in a region corresponding to the photodiode; and
forming a color filter so as to fill the inside of the trench.

10. The method according to claim 9, wherein forming the trench comprises etching the IMD until a top surface of the insulating layer is exposed.

11. The method according to claim 9, wherein forming the color filter comprises:
forming a color filter layer on the inter metal dielectric including the trench; and
removing portions the color filter layer at regions other than in the trench.

12. The method according to claim 11, wherein forming a color filter layer comprises performing a coating process with a dyable or pigmented resist to fill the trench.

13. The method according to claim 12, wherein removing the portions of the color filter layer at regions other than in the trench comprises performing an exposure and development process with respect to the dyable or pigmented resist.

14. The method according to claim 9, wherein the color filter is formed to have the same height as a top surface of the IMD.

15. The method according to claim 9, wherein the color filter is formed to have a height higher than a top surface of the IMD.

16. The method according to claim 9, further comprising forming a planarization layer on the IMD including the color filter.

17. The method according to claim 9, further comprising forming a barrier layer on the IMD including the trench before forming the color filter.

18. The method according to claim 9, further comprising forming a microlens on the color filter.
